(19) United States
(12) Patent Application Publication
(10) Pub. No.: US 2023/0086793 A1
(43) Pub. Date: Mar. 23, 2023

(54) RADIO FREQUENCY MODULE AND COMMUNICATION DEVICE

(71) Applicant: Murata Manufacturing Co., Ltd., Kyoto (JP)

(72) Inventor: Takahiro KATAMATA, Kyoto (JP)

(21) Appl. No.: 18/058,910

(22) Filed: Nov. 28, 2022

Related U.S. Application Data
(63) Continuation of application No. PCT/JP2021/024770, filed on Jun. 30, 2021.

(30) Foreign Application Priority Data
Jul. 6, 2020 (JP) 2020-116699

(51) Int. Cl. H03F 3/45; H04B 1/04

(52) U.S. Cl. CPC H03F 3/45; H04B 1/04; H04B 2001/0408

(57) ABSTRACT

A decrease in isolation is suppressed when transmitting both a first transmission signal and a second transmission signal in simultaneous communication. A radio frequency module includes a first transformer and a second transformer. The first transformer is included in a first differential power amplifier to amplify the first transmission signal. The second transformer is included in a second differential power amplifier to amplify the second transmission signal to be simultaneously communicated with the first transmission signal. A direction of magnetic flux generated in the first transformer is different from a direction of magnetic flux generated in the second transformer.

### CROSS REFERENCE TO RELATED APPLICATION

This is a continuation of International Application No. PCT/JP2021/024770 filed on Jun. 30, 2021 which claims priority from Japanese Patent Application No. 2020-116699 filed on Jul. 6, 2020. The contents of these applications are incorporated herein by reference in their entireties.

### BACKGROUND OF THE DISCLOSURE

### Field of the Disclosure

The present disclosure generally relates to a radio frequency module and a communication device, and more particularly to a radio frequency module for transmitting a signal and a communication device.

### Description of the Related Art

A technique for performing simultaneous communication such as Carrier Aggregation has been known (see Patent Document 1, for example).

In Patent Document 1, described are a Carrier Aggregation system and the like including RF sources, such as power amplifiers, each associated with an individual carrier (radio frequency signal, for example). In the Carrier Aggregation system, power associated with an individual carrier in an aggregated carrier signal is detected.

Patent Document 1: Japanese Unexamined Patent Application Publication No. 2017-17691

### BRIEF SUMMARY OF THE DISCLOSURE

Meanwhile, when both a first transmission signal and a second transmission signal are transmitted in simultaneous communication, there is a problem that isolation decreases.

The present disclosure has been made in view of the problem described above, and a possible benefit thereof is to provide a radio frequency module and a communication device capable of suppressing a decrease in isolation when both a first transmission signal and a second transmission signal are transmitted in simultaneous communication.

A radio frequency module according to an aspect of the present disclosure includes a first transformer and a second transformer. The first transformer is included in a first differential power amplifier to amplify a first transmission signal. The second transformer is included in a second differential power amplifier to amplify a second transmission signal simultaneously communicated with the first transmission signal. A direction of magnetic flux generated in the first transformer and a direction of magnetic flux generated in the second transformer are different from each other.

A radio frequency module according to an aspect of the present disclosure includes a first balun and a second balun. The first balun is included in a first differential power amplifier to amplify a first transmission signal. The second balun is included in a second differential power amplifier to amplify a second transmission signal simultaneously communicated with the first transmission signal. A direction of magnetic flux generated in the first balun and a direction of magnetic flux generated in the second balun are different from each other.

A radio frequency module according to an aspect of the present disclosure includes a first power amplifier, a second power amplifier, a first inductor, and a second inductor. The first power amplifier amplifies a first transmission signal. The second power amplifier amplifies a second transmission signal simultaneously communicated with the first transmission signal. The first inductor is connected to an output side of the first power amplifier. The second inductor is connected to an output side of the second power amplifier. A direction of magnetic flux generated in the first inductor and a direction of magnetic flux generated in the second inductor are different from each other.

A communication device according to an aspect of the present disclosure includes the radio frequency module and a signal processing circuit to process a radio frequency signal passing through the radio frequency module.

According to the present disclosure, it is possible to suppress a decrease in isolation when both a first transmission signal and a second transmission signal are transmitted in simultaneous communication.

### BRIEF DESCRIPTION OF THE SEVERAL VIEWS OF THE DRAWINGS

FIG. 1 is a diagram for explaining a configuration of a radio frequency module and a communication device according to Embodiment 1.

FIG. 2 is a circuit diagram for explaining a configuration of an amplification unit included in the radio frequency module.

FIG. 3 is a schematic diagram for explaining an arrangement in the amplification unit.

FIG. 4 is a circuit diagram for explaining a configuration of an amplification unit included in a radio frequency module according to Embodiment 2.

FIG. 5 is a schematic diagram for explaining an arrangement in the amplification unit.

### DETAILED DESCRIPTION OF THE DISCLOSURE

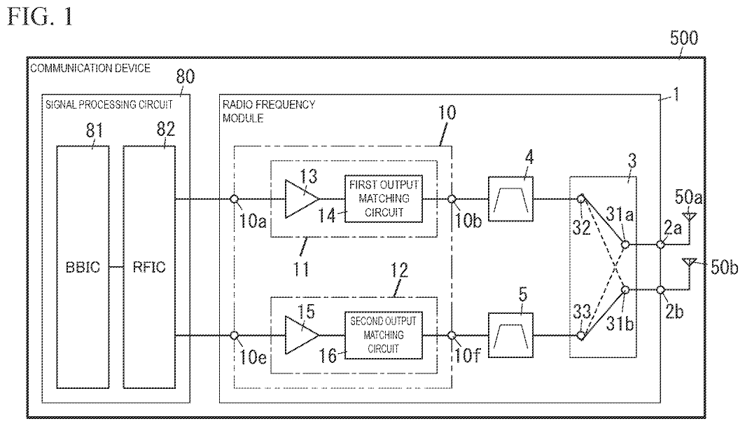

FIG. 1 to FIG. 5 referred to in the following Embodiment 1, Embodiment 2 or the like are all schematic views, and ratios of sizes and thicknesses of constituents in the drawings do not necessarily reflect actual dimensional ratios.

### Embodiment 1

Hereinafter, a radio frequency module 1 and a communication device 500 including the radio frequency module 1 according to Embodiment 1 will be described with reference to FIG. 1 to FIG. 3.

(1) Radio Frequency Module

The radio frequency module 1 according to Embodiment 1 includes antenna terminals 2a and 2b, an antenna switch 3, a first transmission filter 4, a second transmission filter 5, and an amplification unit 10 as illustrated in FIG. 1.

The radio frequency module 1 according to Embodiment 1 is used in the communication device 500 supporting multimode/multiband communication, for example. The communication device 500 is a mobile phone (smartphone, for example), for example, but is not limited thereto, and may be a wearable terminal (smartwatch, for example) or the like, for example. The radio frequency module 1 is a module capable of supporting the 4G (fourth generation mobile communication) standard, the 5G (fifth generation mobile communication) standard, or the like, for example. The 4G standard is the third generation partnership project (3GPP) long term evolution (LTE) standard, for example. The 5G standard is 5G new radio (NR), for example. The radio frequency module 1 is a module capable of supporting Carrier Aggregation and Dual Connectivity. Here, Carrier Aggregation and Dual Connectivity refer to communication that simultaneously uses radio waves in multiple frequency bands.

That is, the radio frequency module 1 according to Embodiment 1 simultaneously performs communication of a signal in a frequency band defined by 4G and communication of a signal in another frequency band defined by 4G. The radio frequency module 1 simultaneously performs communication of a signal in a frequency band defined by 4G and communication of a signal in a frequency band defined by 5G. The radio frequency module 1 simultaneously performs communication of a signal in a frequency band defined by 5G and communication of a signal in another frequency band defined by 5G. Hereinafter, communication by Carrier Aggregation or Dual Connectivity is also referred to as simultaneous communication.

(2) Constituents of Radio Frequency Module

Hereinafter, constituents of the radio frequency module 1 according to Embodiment 1 will be described with reference to the drawings.

As described above, the radio frequency module 1 includes the two antenna terminals 2a and 2b, the antenna switch 3, the first transmission filter 4, the second transmission filter 5, and the amplification unit 10.

The antenna terminal 2a is electrically connected to an antenna 50a as illustrated in FIG. 1. The antenna terminal 2b is electrically connected to an antenna 50b as illustrated in FIG. 1.

The first transmission filter 4 is a filter for a mid-high band. The first transmission filter 4 allows a transmission signal in a first frequency band included in the mid-high band to pass through. In Embodiment 1, the first transmission filter 4 allows a first transmission signal in a first communication band defined by 4G to pass through as a transmission signal in the first frequency band. Here, the first communication band is Band4 (transmission band 1710 MHz to 1755 MHz, reception band 2110 MHz to 2155 MHz) defined by 4G, for example. That is, the first transmission signal is a signal in a frequency band whose transmission band is 1710 MHz to 1755 MHz.

The second transmission filter 5 is a filter for a mid-high band. The second transmission filter 5 allows a transmission signal in a second frequency band included in the mid-high band to pass through. In Embodiment 1, the second transmission filter 5 allows a second transmission signal in a second communication band defined by 4G to pass through as a transmission signal in the second frequency band. Here, the second communication band is Band1 (transmission band 1920 MHz to 1980 MHz, reception band 2110 MHz to 2170 MHz) defined by 4G, for example. That is, the second transmission signal is a signal in a frequency band whose transmission band is 1920 MHz to 1980 MHz.

The antenna switch 3 is a switch for changing over a connection destination of the antenna terminals 2a and 2b (that is, antennas 50a and 50b). The antenna switch 3 has multiple (two in illustrated example) common terminals 31a and 31b, and multiple (two in illustrated example) selection terminals 32 and 33 as illustrated in FIG. 1. The antenna switch 3 selects one of the multiple selection terminals 32 and 33 as a connection destination of one of the common terminal 31a and the common terminal 31b. The antenna switch 3 selects the other of the multiple selection terminals 32 and 33 as a connection destination of the other of the common terminal 31a and the common terminal 31b. That is, the antenna switch 3 selectively connects the first transmission filter 4 and the second transmission filter 5 to the antennas 50a and 50b. The common terminals 31a and 31b are each electrically connected to the antenna terminals 2a and 2b. That is, the common terminal 31a is electrically connected to the antenna 50a through the antenna terminal 2a. The common terminal 31b is electrically connected to the antenna 50b through the antenna terminal 2b. Note that the common terminals 31a and 31b are not limited to being directly connected to the antennas 50a and 50b. A filter, a coupler, or the like may be provided between the common terminals 31a and 31b and the antennas 50a and 50b. The selection terminal 32 is electrically connected to the first transmission filter 4. The selection terminal 33 is electrically connected to the second transmission filter 5. That is, the antenna switch 3 may simultaneously connect the antenna terminal 2a to one of the first transmission filter 4 and the second transmission filter 5, and the antenna terminal 2b to the other of the first transmission filter 4 and the second transmission filter 5.

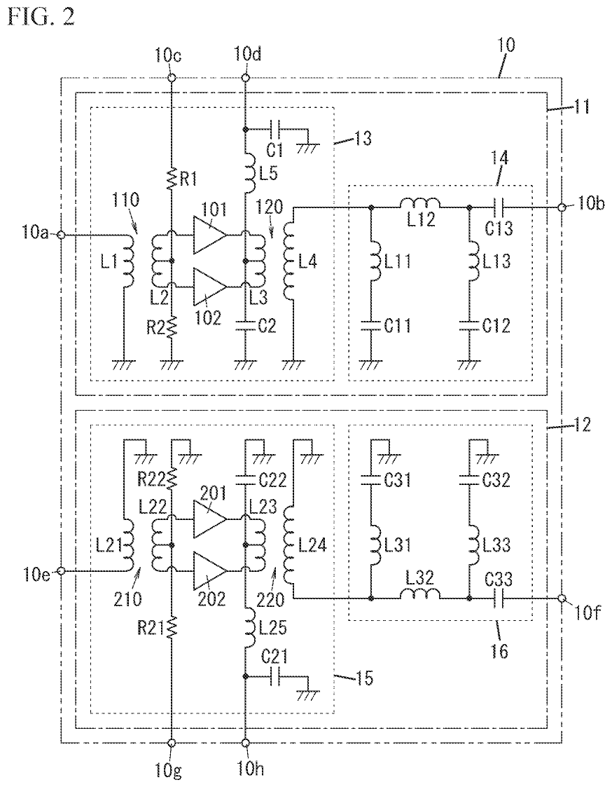

The amplification unit 10 includes a first amplification unit 11 and a second amplification unit 12 as illustrated in FIG. 1. The first amplification unit 11 and the second amplification unit 12 are used for simultaneous communication. The amplification unit 10 includes a first input terminal 10a, a first output terminal 10b, a second input terminal 10e, a second output terminal 10f, and multiple (four in illustrated example) terminals 10c, 10d, 10g, and 10h as illustrated in FIG. 2.

The first amplification unit 11 amplifies the first transmission signal in the first communication band. The first amplification unit 11 amplifies the first transmission signal outputted from a signal processing circuit 80, and outputs the amplified signal to the first transmission filter 4. A detailed configuration of the first amplification unit 11 will be described later.

The second amplification unit 12 amplifies the second transmission signal in the second communication band. The second amplification unit 12 amplifies the second transmission signal outputted from the signal processing circuit 80, and outputs the amplified signal to the second transmission filter 5. A detailed configuration of the second amplification unit 12 will be described later.

(3) Communication Device

The communication device 500 according to Embodiment 1 includes the radio frequency module 1, the signal processing circuit 80, and the antennas 50a and 50b as illustrated in FIG. 1. The signal processing circuit 80 processes a signal passing through the radio frequency module 1. The signal processing circuit 80 includes a baseband signal processing circuit 81 and an RF signal processing circuit 82.

The baseband signal processing circuit 81 is a baseband integrated circuit (BBIC), for example, and is electrically connected to the RF signal processing circuit 82 as illustrated in FIG. 1. The baseband signal processing circuit 81 generates an I-phase signal and a Q-phase signal from a baseband signal. The baseband signal processing circuit 81 processes IQ modulation by combining the I-phase signal and the Q-phase signal, and outputs a transmission signal. At this time, the transmission signal is generated as a modulated signal obtained by performing amplitude modulation to a carrier signal of a predetermined frequency with a period longer than the period of the carrier signal.

The RF signal processing circuit 82 is a radio frequency integrated circuit (RFIC), for example, and is provided between the radio frequency module 1 and the baseband signal processing circuit 81 as illustrated in FIG. 1. The RF signal processing circuit 82 has a function of processing a transmission signal from the baseband signal processing circuit 81, and a function of processing a reception signal received by the antennas 50a and 50b. The RF signal processing circuit 82 is a processing circuit supporting multiband communication, and is able to generate and amplify a transmission signal of multiple communication bands.

Note that, in the communication device 500, the baseband signal processing circuit 81 is not an essential constituent.

(4) First Amplification Unit

Here, a detailed configuration of the first amplification unit 11 will be described with reference to FIG. 1 and FIG. 2.

The first amplification unit 11 includes a first differential power amplifier 13 and a first output matching circuit 14 as illustrated in FIG. 1.

The first differential power amplifier 13 amplifies the first transmission signal. The first differential power amplifier 13 includes a first differential amplification element 101, a second differential amplification element 102, a first balun (unbalanced-balanced conversion circuit) 110, and a first transformer 120 as illustrated in FIG. 2. The first balun 110 includes an input side primary coil L1 and an input side secondary coil L2 as illustrated in FIG. 2. The first transformer 120 includes an output side primary coil L3 and an output side secondary coil L4 as illustrated in FIG. 2.

The first differential power amplifier 13 further includes multiple (two in illustrated example) resistors R1 and R2, multiple (two in illustrated example) capacitors C1 and C2, and a coil L5 as illustrated in FIG. 2.

A first bias voltage is inputted to the terminal 10c included in the amplification unit 10. One end of the resistor R1 is electrically connected to the terminal 10c. The other end of the resistor R1 is electrically connected to one end of the resistor R2. The other end of the resistor R2 is electrically connected to a ground. That is, the resistor R1 and resistor R2 are connected in series between the terminal 10c and the ground. A point between the resistor R1 and the resistor R2 is electrically connected to a point (midpoint, for example) between both ends of the input side secondary coil L2. That is, the other end of the resistor R1 and the one end of the resistor R2 are electrically connected to a point (midpoint, for example) between both the ends of the input side secondary coil L2.

A second bias voltage is inputted to the terminal 10d included in the amplification unit 10. One end of the coil L5 is electrically connected to the terminal 10d. The other end of the coil L5 is connected to one end of the capacitor C2. The other end of the capacitor C2 is electrically connected to the ground. That is, the coil L5 and the capacitor C2 are connected in series between the terminal 10d and the ground. A point between the coil L5 and the capacitor C2 is electrically connected to a point (midpoint, for example) between both ends of the output side primary coil L3. That is, the other end of the coil L5 and the one end of the capacitor C2 are electrically connected to a point (midpoint, for example) between both the ends of the output side primary coil L3.

One end of the capacitor C1 is electrically connected between the coil L5 and the terminal 10d, and the other end of the capacitor C1 is electrically connected to the ground.

The first input terminal 10a of the amplification unit 10 is electrically connected to the RF signal processing circuit 82 of the signal processing circuit 80. The first transmission signal outputted from the RF signal processing circuit 82 is inputted to the first input terminal 10a.

One end of the input side primary coil L1 is electrically connected to the first input terminal 10a, and the other end of the input side primary coil L1 is electrically connected to the ground. One end (first balanced terminal) of the input side secondary coil L2 is electrically connected to the first differential amplification element 101, and the other end (second balanced terminal) of the input side secondary coil L2 is electrically connected to the second differential amplification element 102.

In a state that a first bias voltage is applied to the input side primary coil L1, a radio frequency signal (first transmission signal) outputted from the RF signal processing circuit 82 is inputted to the first input terminal 10a. The first transmission signal is subjected to unbalanced-balanced conversion. At this time, a non-inverting input signal is outputted from the first balanced terminal of the input side secondary coil L2, and an inverting input signal is outputted from the second balanced terminal of the input side secondary coil L2.

The first differential amplification element 101 amplifies a non-inverting input signal outputted from the first balanced terminal of the input side secondary coil L2. The first differential amplification element 101 has an input terminal and an output terminal. The input terminal of the first differential amplification element 101 is electrically connected to the first balanced terminal of the input side secondary coil L2. The output terminal of the first differential amplification element 101 is electrically connected to the output side primary coil L3 of the first transformer 120. Specifically, the output terminal of the first differential amplification element 101 is electrically connected to one end (first end) of the output side primary coil L3.

The second differential amplification element 102 amplifies an inverting input signal outputted from the second balanced terminal of the input side secondary coil L2. The second differential amplification element 102 has an input terminal and an output terminal. The input terminal of the second differential amplification element 102 is electrically connected to the second balanced terminal of the input side secondary coil L2. The output terminal of the second differential amplification element 102 is electrically connected to the output side primary coil L3 of the first transformer 120. Specifically, the output terminal of the second differential amplification element 102 is electrically connected to the other end (second end) of the output side primary coil L3.

The first end of the output side primary coil L3 of the first transformer 120 is electrically connected to the first differential amplification element 101, and the second end of the output side primary coil L3 is electrically connected to the second differential amplification element 102. The second bias voltage is supplied to a midpoint of the output side primary coil L3 of the first transformer 120. One terminal of the output side secondary coil L4 is electrically connected to the first output terminal 10b, and the other terminal of the output side secondary coil L4 is connected to the ground. In other words, the first transformer 120 is electrically connected between the output terminals of the first differential amplification element 101 and the second differential amplification element 102, and the first output terminal 10b.

The non-inverting input signal amplified by the first differential amplification element 101 and the inverting input signal amplified by the second differential amplification element 102 are converted in impedance by the first transformer 120 while maintaining the opposite phases.

The first output matching circuit 14 is connected to an output side of the first differential power amplifier 13. The first output matching circuit 14 includes multiple (three in illustrated example) inductors L11, L12, and L13, and multiple (three in illustrated example) capacitors C11, C12, and C13 as illustrated in FIG. 2. That is, the multiple inductors L11, L12, and L13 are connected to the output side of the first differential power amplifier 13.

The inductor L12 is electrically connected between one terminal of the output side secondary coil L4 and the first output terminal 10b. The capacitor C13 is electrically connected between the inductor L12 and the first output terminal 10b. That is, the inductor L12 and the capacitor C13 are connected in series between the one terminal of the output side secondary coil L4 and the first output terminal 10b.

One end of the inductor L11 is electrically connected between the one terminal of the output side secondary coil L4 and the inductor L12, and the other end of the inductor L11 is electrically connected to the ground. One end of the capacitor C11 is electrically connected to the other end of the inductor L11, and the other end of the capacitor C11 is electrically connected to the ground. That is, the inductor L11 and the capacitor C11 are connected in series between the ground and a point between the one terminal of the output side secondary coil L4 and the inductor L12.

One end of the inductor L13 is electrically connected between the inductor L12 and the capacitor C13, and the other end of the inductor L13 is electrically connected to the ground. One end of the capacitor C12 is electrically connected to the other end of the inductor L13, and the other end of the capacitor C12 is electrically connected to the ground. That is, the inductor L13 and the capacitor C12 are connected in series between the ground and a point between the inductor L12 and the capacitor C13.

With the configuration above, the first output matching circuit 14 performs impedance matching between the first differential power amplifier 13 and the first transmission filter 4. Specifically, a non-inverting input signal amplified by the first differential amplification element 101 and an inverting input signal amplified by the second differential amplification element 102 are converted in impedance by the first transformer 120 and the first output matching circuit 14 while maintaining the opposite phases. With this, the output impedance of the first amplification unit 11 at the first output terminal 10b is matched with the input impedance of the first transmission filter 4.

(5) Second Amplification Unit

Here, a detailed configuration of the second amplification unit 12 will be described with reference to FIG. 1 and FIG. 2.

The second amplification unit 12 includes a second differential power amplifier 15 and a second output matching circuit 16 as illustrated in FIG. 1. The first differential power amplifier 13 and the second differential power amplifier 15 are used for simultaneous communication.

The second differential power amplifier 15 amplifies the second transmission signal. The second differential power amplifier 15 includes a third differential amplification element 201, a fourth differential amplification element 202, a second balun 210, and a second transformer 220 as illustrated in FIG. 2. The second balun 210 includes an input side tertiary coil L21 and an input side quaternary coil L22 as illustrated in FIG. 2. The second transformer 220 includes an output side tertiary coil L23 and an output side quaternary coil L24 as illustrated in FIG. 2.

The second differential power amplifier 15 further includes multiple (two in illustrated example) resistors R21 and R22, multiple (two in illustrated example) capacitors C21 and C22, and a coil L25 as illustrated in FIG. 2.

A third bias voltage is inputted to the terminal 10g included in the amplification unit 10. One end of the resistor R21 is electrically connected to the terminal 10g. The other end of the resistor R21 is electrically connected to one end of the resistor R22. The other end of the resistor R22 is electrically connected to the ground. That is, the resistor R21 and the resistor R22 are connected in series between the terminal 10g and the ground. A point between the resistor R21 and the resistor R22 is electrically connected to a point (midpoint, for example) between both ends of the input side quaternary coil L22. That is, the other end of the resistor R21 and the one end of the resistor R22 are electrically connected to a point (midpoint, for example) between both ends of the input side quaternary coil L22.

A fourth bias voltage is inputted to the terminal 10h included in the amplification unit 10. One end of the coil L25 is electrically connected to the terminal 10h. The other end of the coil L25 is connected to one end of the capacitor C22. The other end of the capacitor C22 is electrically connected to the ground. That is, the coil L25 and the capacitor C22 are connected in series between the terminal 10h and the ground. A point between the coil L25 and the capacitor C22 is electrically connected to a point (midpoint, for example) between both ends of the output side tertiary coil L23. That is, the other end of the coil L25 and the one end of the capacitor C22 are electrically connected to a point (midpoint, for example) between both the ends of the output side tertiary coil L23.

One end of the capacitor C21 is electrically connected between the coil L25 and the terminal 10h, and the other end of the capacitor C21 is electrically connected to the ground.

The second input terminal 10e of the amplification unit 10 is electrically connected to the RF signal processing circuit 82 of the signal processing circuit 80. The second transmission signal outputted from the RF signal processing circuit 82 is inputted to the second input terminal 10e.

One end of the input side tertiary coil L21 is electrically connected to the second input terminal 10e, and the other end of the input side tertiary coil L21 is electrically connected to the ground. One end (first balanced terminal) of the input side quaternary coil L22 is electrically connected to the fourth differential amplification element 202, and the other end (second balanced terminal) of the input side quaternary coil L22 is electrically connected to the fourth differential amplification element 202.

In a state that a third bias voltage is applied to the input side tertiary coil L21, the radio frequency signal (second transmission signal) outputted from the RF signal processing circuit 82 is inputted to the second input terminal 10e. The second transmission signal is subjected to unbalanced-balanced conversion. At this time, a non-inverting input signal is outputted from the second balanced terminal of the input side quaternary coil L22, and an inverting input signal is outputted from the second balanced terminal of the input side quaternary coil L22.

The third differential amplification element 201 amplifies a non-inverting input signal outputted from the first balanced terminal of the input side quaternary coil L22. The third differential amplification element 201 has an input terminal and an output terminal. The input terminal of the third differential amplification element 201 is electrically connected to the first balanced terminal of the input side quaternary coil L22. The output terminal of the third differential amplification element 201 is electrically connected to the output side tertiary coil L23 of the second transformer 220. Specifically, the output terminal of the third differential amplification element 201 is electrically connected to one end (first end) of the output side tertiary coil L23.

The fourth differential amplification element 202 amplifies an inverting input signal outputted from the second balanced terminal of the input side quaternary coil L22. The fourth differential amplification element 202 has an input terminal and an output terminal. The input terminal of the fourth differential amplification element 202 is electrically connected to the second balanced terminal of the input side quaternary coil L22. The output terminal of the fourth differential amplification element 202 is electrically connected to the output side tertiary coil L23 of the second transformer 220. Specifically, the output terminal of the fourth differential amplification element 202 is electrically connected to the other end (second end) of the output side tertiary coil L23.

The first end of the output side tertiary coil L23 of the second transformer 220 is electrically connected to the third differential amplification element 201, and the second end of the output side tertiary coil L23 is electrically connected to the fourth differential amplification element 202. In the second transformer 220, the fourth bias voltage is supplied to the midpoint of the output side tertiary coil L23. One terminal of the output side quaternary coil L24 is electrically connected to the second output terminal 10f, and the other terminal of the output side quaternary coil L24 is connected to the ground. In other words, the second transformer 220 is electrically connected between the output terminals of the third differential amplification element 201 and the fourth differential amplification element 202, and the second output terminal 10f.

The non-inverting input signal amplified by the third differential amplification element 201 and the inverting input signal amplified by the fourth differential amplification element 202 are converted in impedance by the second transformer 220 while maintaining the opposite phases.

The second output matching circuit 16 is connected to an output side of the second differential power amplifier 15. The second output matching circuit 16 includes multiple (three in illustrated example) inductors L31, L32, and L33, and multiple (three in illustrated example) capacitors C31, C32, and C33 as illustrated in FIG. 2. That is, the multiple inductors L31, L32 and L33 are connected to the output side of the second differential power amplifier 15.

The inductor L32 is electrically connected between the one terminal of the output side quaternary coil L24 and the second output terminal 10f. The capacitor C33 is electrically connected between the inductor L32 and the second output terminal 10f. That is, the inductor L32 and the capacitor C33 are connected in series between the one terminal of the output side quaternary coil L24 and the second output terminal 10f.

One end of the inductor L31 is electrically connected between the one terminal of the output side quaternary coil L24 and the inductor L32, and the other end of the inductor L31 is electrically connected to the ground. One end of the capacitor C11 is electrically connected to the other end of the inductor L31, and the other end of the capacitor C31 is electrically connected to the ground. That is, the inductor L31 and the capacitor C31 are connected in series between the ground and a point between the one terminal of the output side quaternary coil L24 and the inductor L32.

One end of the inductor L33 is electrically connected between the inductor L32 and the capacitor C33, and the other end of the inductor L33 is electrically connected to the ground. One end of the capacitor C32 is electrically connected to the other end of the inductor L33, and the other end of the capacitor C32 is electrically connected to the ground. That is, the inductor L33 and the capacitor C32 are connected in series between the ground and a point between the inductor L32 and the capacitor C33.

With the configuration above, the second output matching circuit 16 performs impedance matching between the second differential power amplifier 15 and the second transmission filter 5. Specifically, a non-inverting input signal amplified by the third differential amplification element 201 and an inverting input signal amplified by the fourth differential amplification element 202 are converted in impedance by the second transformer 220 and the second output matching circuit 16 while maintaining the opposite phases. With this, the output impedance of the second amplification unit 12 at the second output terminal 10f is matched with the input impedance of the second transmission filter 5.

(6) Arrangement Configuration

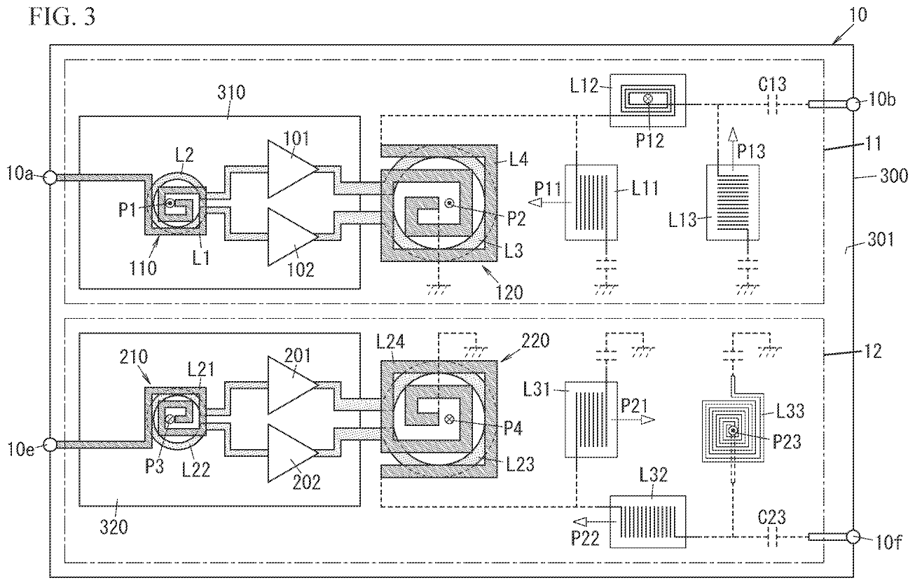

Here, the arrangement configuration of the first amplification unit 11 and the second amplification unit 12 will be described with reference to FIG. 3. Note that, in FIG. 3, a direction in which the first input terminal 10a and the first output terminal 10b are arranged is defined as a right and left direction. In FIG. 3, a direction in which the first input terminal 10a and the second input terminal 10e are arranged is defined as a front and back direction. Further, in FIG. 3, a direction (front and back direction of paper surface) orthogonal to both the right and left direction and the front and back direction is defined as an up and down direction. A direction from the first input terminal 10a toward the first output terminal 10b is defined as a rightward direction, and a direction from the first output terminal 10b toward the first input terminal 10a is defined as a leftward direction. A direction from the first input terminal 10a toward the second input terminal 10e is defined as a forward direction, and a direction from the second input terminal 10e toward the first input terminal 10a is defined as a backward direction. A direction from the inside of a substrate 300 toward a mounting surface 301 is defined as an upward direction, and a direction from the mounting surface 301 toward the inside of the substrate 300 is defined as a downward direction.

The first amplification unit 11 and the second amplification unit 12 are provided in or on the substrate 300.

First, the arrangement in the first amplification unit 11 will be described.

The first differential amplification element 101, the second differential amplification element 102, and the first balun 110 are integrated into one chip. That is, a first chip 310 includes the first differential amplification element 101, the second differential amplification element 102, and the first balun 110 (see FIG. 3). The first differential amplification element 101, the second differential amplification element 102, and the first balun 110 are arranged inside the first chip 310. The first chip 310 is arranged on the mounting surface 301 of the substrate 300. Note that the first chip 310 may partially be buried in the substrate 300. Although the first differential amplification element 101, the second differential amplification element 102, and the first balun 110 are arranged inside the first chip 310, they are illustrated with the solid lines in FIG. 3.

The input side primary coil L1 of the first balun 110 is wound counterclockwise starting from one end, which is closer to the first input terminal 10a, of both ends of the input side primary coil L1. The input side secondary coil L2 of the first balun 110 is provided inside the first chip 310 at a position closer than the input side primary coil L1 to the substrate 300. The input side primary coil L1 is arranged to overlap the input side secondary coil L2 in plan view of the substrate 300.

The output side primary coil L3 of the first transformer 120 is formed inside the substrate 300. The output side secondary coil L4 of the first transformer 120 is wound clockwise starting from one end, which is closer to the first output terminal 10b, of both ends of the output side secondary coil L4. The output side secondary coil L4 is arranged to overlap the output side primary coil L3 in plan view of the substrate 300. Although the output side primary coil L3 is arranged inside the substrate 300, it is illustrated with the solid line in FIG. 3.

The multiple (three in illustrated example) inductors L11, L12, and L13 are formed of inductor chips each having a substantially rectangular parallelepiped shape. The inductors L11, L12, and L13 are arranged on the mounting surface 301 of the substrate 300. Note that the inductors L11, L12, and L13 may partially be buried in the substrate 300.

A conductive wire is wound while making a winding axis, extending along a direction orthogonal to a long-side direction, as a center to form each of inductors L11 and L12. A conductive wire is wound while making a winding axis, extending along a long-side direction, as a center to form the inductor L13. That is, the inductors L11 and L12 have internal structures different from an internal structure of the inductor L13.

The inductors L11, L12, and L13 are arranged such that the directions of the generated magnetic flux are different from each other. For example, the inductor L11 is arranged such that the generated magnetic flux P11 is directed leftward in plan view of the substrate 300. The inductor L12 is arranged such that the generated magnetic flux P12 is directed downward in plan view of the substrate 300. The inductor L13 is arranged such that the generated magnetic flux P13 is directed backward in plan view of the substrate 300.

Next, the arrangement in the second amplification unit 12 will be described.

The third differential amplification element 201, the fourth differential amplification element 202, and the second balun 210 are integrated into one chip. That is, a second chip 320 includes the third differential amplification element 201, the fourth differential amplification element 202, and the second balun 210 (see FIG. 3). The third differential amplification element 201, the fourth differential amplification element 202, and the second balun 210 are arranged inside the second chip 320. The second chip 320 is arranged on the mounting surface 301 of the substrate 300. Note that the second chip 320 may partially be buried in the substrate 300. Although the third differential amplification element 201, the fourth differential amplification element 202, and the second balun 210 are arranged inside the second chip 320, they are illustrated with the solid lines in FIG. 3.

The input side tertiary coil L21 of the second balun 210 is wound clockwise starting from one end, which is closer to the second input terminal 10e, of both ends of the input side tertiary coil L21. The input side quaternary coil L22 of the second balun 210 is provided inside the second chip 320 at a position closer than the input side tertiary coil L21 to the substrate 300. The input side tertiary coil L21 is arranged to overlap the input side quaternary coil L22 in plan view of the substrate 300.

The output side tertiary coil L23 of the second transformer 220 is formed inside the substrate 300. The output side quaternary coil L24 of the second transformer 220 is wound counterclockwise starting from one end, which is closer to the second output terminal 10f, of both ends of the output side quaternary coil L24. The output side quaternary coil L24 is arranged to overlap the output side tertiary coil L23 in plan view of the substrate 300. Although the output side tertiary coil L23 is arranged inside the substrate 300, it is illustrated with the solid line in FIG. 3.

The multiple (three in illustrated example) inductors L31 and L32 are formed of inductor chips each having a substantially rectangular parallelepiped shape. The inductors L31 and L32 are arranged on the mounting surface 301 of the substrate 300. Note that the inductors L31 and L32 may partially be buried in the substrate 300.

A conductive wire is wound while making a winding axis, extending along a direction orthogonal to a long-side direction, as a center to form the inductor L31. A conductive wire is wound while making a winding axis, extending along a long-side direction, as a center to form the inductor L32. That is, the inductors L31 and L32 have internal structures different from each other.

The inductor L33 is formed of a conductive pattern. The inductor L33 is formed counterclockwise starting from one end, which is closer to the second output terminal 10f, of both ends of the inductor L33.

The inductors L31, L32, and L33 are arranged such that the directions of the generated magnetic flux are different from each other. For example, the inductor L31 is arranged such that the generated magnetic flux P21 is directed rightward in plan view of the substrate 300. The inductor L32 is arranged such that the generated magnetic flux P22 is directed leftward in plan view of the substrate 300. The inductor L33 is arranged such that the generated magnetic flux P23 is directed upward in plan view of the substrate 300.

Here, the inductor L11 and the inductor L31 are present at relatively the same position in a circuit forming the first amplification unit 11 and a circuit forming the second amplification unit 12. Further, the direction of the magnetic flux P11 generated in the inductor L11 is the leftward direction, and the direction of the magnetic flux P21 generated in the inductor L31 is the rightward direction. The inductor L12 and the inductor L32 are present at relatively the same position in the circuit forming the first amplification unit 11 and the circuit forming the second amplification unit 12. Further, the direction of the magnetic flux P12 generated in the inductor L31 is the downward direction, and the direction of the magnetic flux P22 generated in the inductor L32 is the leftward direction. The inductor L13 and the inductor L33 are present at relatively the same position in the circuit forming the first amplification unit 11 and the circuit forming the second amplification unit 12. Further, the direction of the magnetic flux P13 generated in the inductor L13 is the backward direction, and the direction of the magnetic flux P23 generated in the inductor L33 is the upward direction.

That is, with respect to the first output matching circuit 14 and the second output matching circuit 16, for each pair of inductors arranged at relatively the same position as circuits, one inductor (first inductor) and the other inductor (second inductor) of a pair are arranged such that the directions of the magnetic flux generated in the first inductor and the second inductor of the pair are different from each other. In other words, with respect to the multiple first inductors (inductors L11, L12, and L13) and the multiple second inductors (inductors L31, L32, and L33), for each pair of inductors arranged at relatively the same position as circuits, the directions of the magnetic flux generated in the first inductor and the second inductor of a pair are different from each other.

Note that, with respect to the first output matching circuit 14 and the second output matching circuit 16, in the pairs of inductors arranged at relatively the same position as circuits, it is not necessary to arrange the first inductor and the second inductor of a pair such that the directions of the magnetic flux are different from each other in all pairs. With respect to the first output matching circuit 14 and the second output matching circuit 16, in the pairs of inductors arranged at relatively the same position as circuits, it is sufficient to arrange the first inductor and the second inductor of a pair such that the directions of the magnetic flux are different from each other in at least one pair.

Further, a conductor forming the input side primary coil L1 of the first balun 110 is wound counterclockwise, and a conductor forming the input side tertiary coil L21 of the second balun 210 is wound clockwise. As a result, the direction of magnetic flux P1 generated by a current flowing through the input side primary coil L1 is the upward direction, and the direction of magnetic flux P3 generated by a current flowing through the input side tertiary coil L21 is the downward direction. That is, when the first transmission signal is inputted to the first input terminal 10a, that is, when a current is inputted to the first input terminal 10a, the magnetic flux P1 is generated in the upward direction in the first balun 110. When the second transmission signal is inputted to the second input terminal 10e, that is, when a current is inputted to the second input terminal 10e, the magnetic flux P3 is generated in the downward direction in the second balun 210. That is, the first balun 110 and the second balun 210 are configured such that the directions of the generated magnetic flux are different from each other.

A conductor forming the output side secondary coil L4 of the first transformer 120 is wound clockwise, and a conductor forming the output side quaternary coil L24 of the second transformer 220 is wound counterclockwise. As a result, the direction of magnetic flux P2 generated by a current flowing through the output side secondary coil L4 is the upward direction, and the direction of magnetic flux P4 generated by a current flowing through the output side quaternary coil L24 is the downward direction. That is, when the first transmission signal is inputted to the first transformer 120, that is, when a current is inputted to the first transformer 120, the magnetic flux P2 is generated in the upward direction in the first transformer 120. When the second transmission signal is inputted to the second transformer 220, that is, when a current is inputted to the second transformer 220, the magnetic flux P4 is generated in the downward direction in the second transformer 220. That is, the first transformer 120 and the second transformer 220 are configured such that the directions of the generated magnetic flux are different from each other.

That is, the radio frequency module 1 of Embodiment 1 is configured such that first magnetic flux (magnetic flux P1, for example) generated on the input side of the first differential power amplifier 13 and second magnetic flux (magnetic flux P3, for example) generated on the input side of the second differential power amplifier 15 have directions different from each other. Further, the radio frequency module 1 of Embodiment 1 is configured such that the third magnetic flux (magnetic flux P2, for example) generated on the output side of the first differential power amplifier 13 and the fourth magnetic flux (magnetic flux P4, for example) generated on the output side of the second differential power amplifier 15 have directions different from each other.

Note that, it is not necessary that both the following conditions are met. The first condition is that the first balun 110 and the second balun 210 are configured such that the directions of the generated magnetic flux are different from each other. The second condition is that the first transformer 120 and the second transformer 220 are configured such that the directions of the generated magnetic flux are different from each other. It is sufficient that the first differential power amplifier 13 and the second differential power amplifier 15 are provided to realize at least one of the configurations described as follows. The first configuration is a configuration in which the first magnetic flux (magnetic flux P1) generated on the input side of the first differential power amplifier 13 and the second magnetic flux (magnetic flux P3) generated on the input side of the second differential power amplifier 15 have directions different from each other. The second configuration is a configuration in which the third magnetic flux (magnetic flux P2) generated on the output side of the first differential power amplifier 13 and the fourth magnetic flux (magnetic flux P4) generated on the output side of the second differential power amplifier 15 have directions different from each other. That is, the first configuration is realized when the first balun 110 and the second balun 210 are configured such that the directions of the generated magnetic flux are different from each other. The second configuration is realized when the first transformer 120 and the second transformer 220 are configured such that the directions of the generated magnetic flux are different from each other.

Although the winding direction of the input side primary coil L1 of the first balun 110 and the winding direction of the input side tertiary coil L21 of the second balun 210 are described as different from each other, the present disclosure is not limited to this configuration. The winding direction of the input side secondary coil L2 of the first balun 110 and the winding direction of the input side quaternary coil L22 of the second balun 210 may be different from each other. Alternatively, the winding direction of the input side primary coil L1 of the first balun 110 and the winding direction of the input side quaternary coil L22 of the second balun 210 may be different from each other. Alternatively, the winding direction of the input side secondary coil L2 of the first balun 110 and the winding direction of the input side tertiary coil L21 of the second balun 210 may be different from each other. That is, it is sufficient that the winding direction of one coil of the input side primary coil L1 and the input side secondary coil L2 of the first balun 110, and the winding direction of one coil of the input side tertiary coil L21 and the input side quaternary coil L22 of the second balun 210 are configured different from each other.

Although the winding direction of the output side secondary coil L4 of the first transformer 120 and the winding direction of the output side quaternary coil L24 of the second transformer 220 are described as different from each other, the present disclosure is not limited to this configuration. The winding direction of the output side primary coil L3 of the first transformer 120 and the winding direction of the output side tertiary coil L23 of the second transformer 220 may be different from each other. Alternatively, the winding direction of the output side primary coil L3 of the first transformer 120 and the winding direction of the output side quaternary coil L24 of the second transformer 220 may be different from each other. Alternatively, the winding direction of the output side secondary coil L4 of the first transformer 120 and the winding direction of the output side tertiary coil L23 of the second transformer 220 may be different from each other. That is, it is sufficient that the winding direction of one coil of the output side primary coil L3 and the output side secondary coil L4 of the first transformer 120, and the winding direction of one coil of the output side tertiary coil L23 and the output side quaternary coil L24 of the second transformer 220 are configured different from each other.

(7) Operation Example of Radio Frequency Module

Hereinafter, an operation of the radio frequency module 1 when simultaneous communication is performed will be described with reference to FIG. 1.

In this case, the antenna switch 3 connects the antenna terminal 2a to one filter of the first transmission filter 4 and the second transmission filter 5, and connects the antenna terminal 2b to the other filter of the first transmission filter 4 and the second transmission filter 5. That is, the antenna switch 3 selects one selection terminal of the selection terminal 32 and the selection terminal 33 as a connection destination of the common terminal 31a, and selects the other selection terminal of the selection terminal 32 and the selection terminal 33 as a connection destination of the common terminal 31b.

The first transmission signal outputted from the signal processing circuit 80 is transmitted from one of the antenna 50a and the antenna 50b (antenna 50a, for example) through the first amplification unit 11 and the first transmission filter 4. The second transmission signal outputted from the signal processing circuit 80 is transmitted from one of the antenna 50a and the antenna 50b (antenna 50b, for example) through the second amplification unit 12 and the second transmission filter 5.

(8) Advantageous Effects

As described above, the radio frequency module 1 of Embodiment 1 includes the first transformer 120 and the second transformer 220. The first transformer 120 is included in the first differential power amplifier 13 to amplify the first transmission signal. The second transformer 220 is included in the second differential power amplifier 15 to amplify the second transmission signal to be simultaneously communicated with the first transmission signal. The direction of the magnetic flux P2 generated in the first transformer 120 and the direction of the magnetic flux P4 generated in the second transformer 220 are different from each other.

With the configuration above, in the first transformer 120 and the second transformer 220, the directions of the generated magnetic flux are different from each other. Accordingly, the magnetic flux P2 generated in the first transformer 120 and the magnetic flux P4 generated in the second transformer 220 are not coupled to each other. That is, it is possible to suppress a decrease in isolation when the first transmission signal and the second transmission signal are transmitted in simultaneous communication.

Further, the radio frequency module 1 of Embodiment 1 includes the first balun 110 and the second balun 210. The first balun 110 is included in the first differential power amplifier 13 to amplify the first transmission signal. The second balun 210 is included in the second differential power amplifier 15 to amplify the second transmission signal to be simultaneously communicated with the first transmission signal. The direction of the magnetic flux P1 generated in the first balun 110 and the direction of the magnetic flux P3 generated in the second balun 210 are different from each other.

With the configuration above, in the first balun 110 and the second balun 210, the directions of the generated magnetic flux are different from each other. Accordingly, the magnetic flux P1 generated in the first balun 110 and the magnetic flux P3 generated in the second balun 210 are not coupled to each other. That is, it is possible to suppress a decrease in isolation when the first transmission signal and the second transmission signal are transmitted in simultaneous communication.

Further, the radio frequency module 1 of Embodiment 1 includes a first power amplifier (first differential power amplifier 13, for example), a second power amplifier (second differential power amplifier 15, for example), a first inductor (inductor L11, for example), and a second inductor (inductor L31, for example). The first power amplifier amplifies the first transmission signal. The second power amplifier amplifies the second transmission signal simultaneously communicated with the first transmission signal. The first inductor is connected to an output side of the first power amplifier. The second inductor is connected to an output side of the second power amplifier. The direction of the magnetic flux (magnetic flux P11, for example) generated in the first inductor and the direction of the magnetic flux (magnetic flux P21, for example) generated in the second inductor are different from each other.

With the configuration above, in the first inductor and the second inductor, the directions of the generated magnetic flux are different from each other. Accordingly, the magnetic flux generated in the first inductor and the magnetic flux generated in the second inductor are not coupled to each other. That is, it is possible to suppress a decrease in isolation when the first transmission signal and the second transmission signal are transmitted in simultaneous communication.

(9) Modification

Hereinafter, modifications of Embodiment 1 will be described.

(9.1) Modification 1

In Embodiment 1, the first output matching circuit 14 and the second output matching circuit 16 have a configuration in which a pair of inductors that generate magnetic flux in directions different from each other is a pair of inductors arranged at relatively the same position as circuits. However, the present disclosure is not limited to this configuration.

In the multiple first inductors included in the first output matching circuit 14 and the multiple second inductors included in the second output matching circuit 16, for each pair of the first inductor and the second inductor based on a distance, the first inductor and the second inductor of a pair may be arranged such that the directions of the magnetic flux generated in the first inductor and the second inductor of the pair are different from each other.

For example, the inductor L11 and the inductor closest to the arrangement position of the inductor L11 among the multiple inductors L31, L32, and L33 of the second output matching circuit 16 are defined as a pair of inductors in which the directions of the generated magnetic flux are different from each other. Similarly, the inductor L12 and the inductor closest to the arrangement position of the inductor L12 among the multiple inductors L31, L32, and L33 of the second output matching circuit 16 are defined as a pair of inductors in which the directions of the generated magnetic flux are different from each other. The inductor L13 and the inductor closest to the arrangement position of the inductor L13 among the multiple inductors L31, L32, and L33 of the second output matching circuit 16 are defined as a pair of inductors in which the directions of the generated magnetic flux are different from each other.

(9.2) Modification 2

In Embodiment 1, the radio frequency module 1 is configured such that the directions of the magnetic flux generated in the first differential power amplifier 13 and the second differential power amplifier 15 are different from each other, and the directions of the magnetic flux generated in the first output matching circuit 14 and the second output matching circuit 16 are different from each other. However, the present disclosure is not limited to this configuration.

The radio frequency module 1 may be configured such that the directions of the generated magnetic flux are different from each other only in the first differential power amplifier 13 and the second differential power amplifier 15. In this case, as described above, it is sufficient that the radio frequency module 1 is configured to realize at least one configuration of the first configuration and the second configuration. The first configuration is a configuration in which the first magnetic flux (magnetic flux P1) generated on the input side of the first differential power amplifier 13 and the second magnetic flux (magnetic flux P3) generated on the input side of the second differential power amplifier 15 have directions different from each other. The second configuration is a configuration in which the third magnetic flux (magnetic flux P2) generated on the output side of the first differential power amplifier 13 and the fourth magnetic flux (magnetic flux P4) generated on the output side of the second differential power amplifier 15 have directions different from each other.

Alternatively, the radio frequency module 1 may be configured such that the directions of the generated magnetic flux are different from each other only in the first output matching circuit 14 and the second output matching circuit 16. In this case, it is not necessary that both the power amplifier connected to the first output matching circuit 14 and the power amplifier connected to the second output matching circuit 16 are differential power amplifiers. That is, the power amplifier connected to the first output matching circuit 14 and the power amplifier connected to the second output matching circuit 16 may be power amplifiers different from the differential power amplifiers. That is, the radio frequency module 1 may have the following configuration. The radio frequency module 1 includes the first power amplifier, the second power amplifier, the first output matching circuit 14, and the second output matching circuit 16. The first power amplifier amplifies the first transmission signal. The second power amplifier amplifies the second transmission signal. The first output matching circuit 14 performs impedance matching of a signal outputted from the first power amplifier. The second output matching circuit 16 performs impedance matching of a signal outputted from the second power amplifier. The first output matching circuit 14 and the second output matching circuit 16 are provided such that the first magnetic flux generated in the first output matching circuit 14 and the second magnetic flux generated in the second output matching circuit have directions different from each other.

(9.3) Modification 3

In Embodiment 1, transmission in Band4 and Band11 which are communication bands of the 4G standard is exemplified as simultaneous communication. However, the simultaneous communication may be communication (transmission) in a communication band of the 4G standard and a communication band of the 5G standard. That is, one transmission signal of the first transmission signal and the second transmission signal is a signal in the first frequency band defined by the fourth generation mobile communication standard, and the other transmission signal of the first transmission signal and the second transmission signal is a signal in the second frequency band defined by the fifth generation mobile communication standard.

Alternatively, the simultaneous communication may be communication (transmission) in the first communication band of the 5G standard and the second communication band of the 5G standard. That is, the first transmission signal is a signal of the first frequency band defined by the fifth generation mobile communication standard, and the second transmission signal is a signal of the second frequency band defined by the fifth generation mobile communication standard.

(9.4) Modification 4

In Embodiment 1, the first output matching circuit 14 and the second output matching circuit 16 are configured to include multiple inductors, but are not limited to this configuration. Each of the first output matching circuit 14 and the second output matching circuit 16 may include one inductor.

(9.5) Modification 5

In Embodiment 1, the first amplification unit 11 and the second amplification unit 12 may be configured as one module.

(9.6) Modification 6

In Embodiment 1, the radio frequency module 1 is configured to perform simultaneous communication using the two antennas 50a and 50b, but is not limited to this configuration. The radio frequency module 1 may be configured to perform simultaneous communication using one antenna.

### Embodiment 2

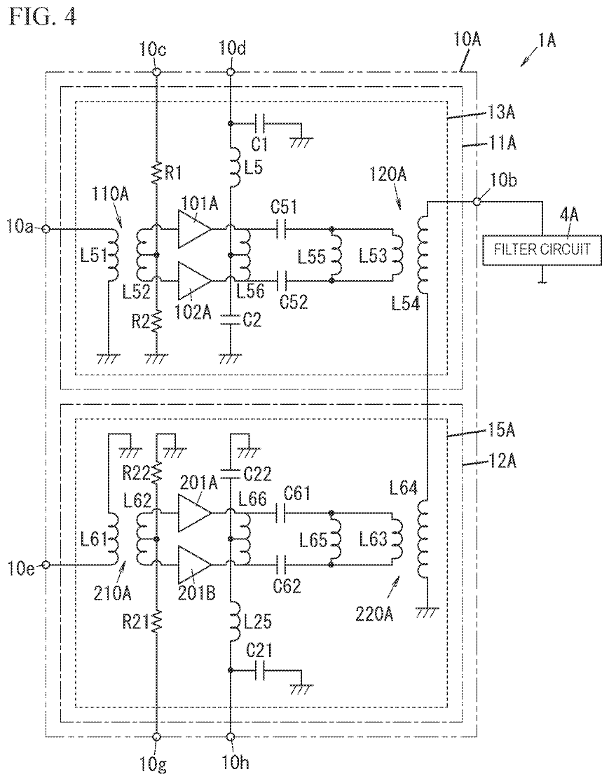

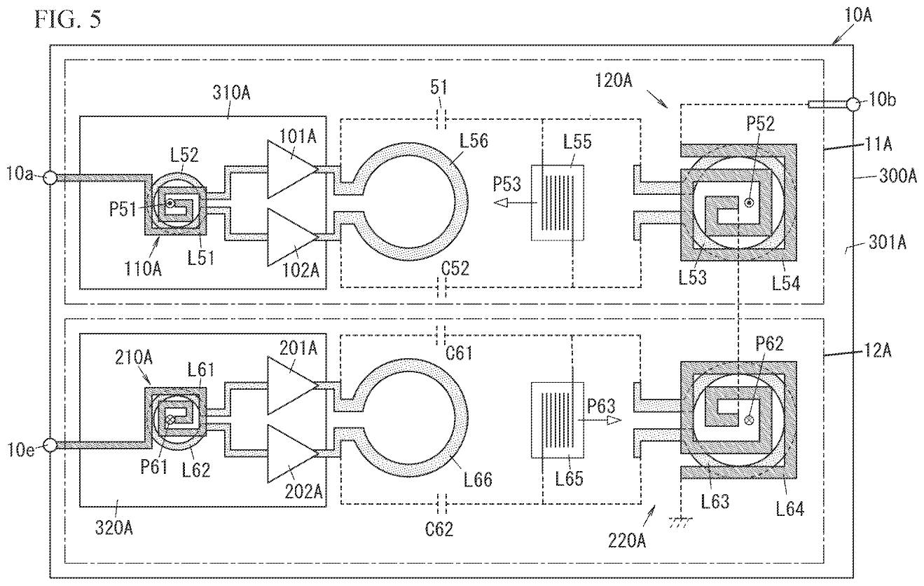

Hereinafter, a radio frequency module 1A and an amplification unit 10A according to Embodiment 2 will be described with reference to FIG. 4 and FIG. 5. With respect to the radio frequency module 1A and the amplification unit 10A according to Embodiment 2, the same constituents as those of the radio frequency module 1 and the amplification unit 10 according to Embodiment 1 are denoted by the same signs, and a description thereof is omitted.

(1) Configuration

The radio frequency module 1A according to Embodiment 2 includes the amplification unit 10A and a filter circuit 4A as illustrated in FIG. 4.

The amplification unit 10A includes a first amplification unit 11A (Peaking Amplifier/Aux Amplifier) and a second amplification unit 12A (Main Amplifier/Carrier Amplifier) as illustrated in FIG. 4. The first amplification unit 11 and the second amplification unit 12 are used for simultaneous communication.

The first amplification unit 11A amplifies the first transmission signal in the first communication band. The first amplification unit 11A amplifies the first transmission signal outputted from the signal processing circuit 80 (see FIG. 1) and outputs the amplified signal to the filter circuit 4A. The second amplification unit 12A amplifies the second transmission signal in the second communication band. The second amplification unit 12A amplifies the second transmission signal outputted from the signal processing circuit 80 and outputs the amplified signal to the filter circuit 4A.

The filter circuit 4A is a filter having a pass band that is a transmission band of a specific communication band. The filter circuit 4A includes a frequency band of the first transmission signal and a frequency band of the second transmission signal. The filter circuit 4A is a one chip acoustic wave filter, for example, and multiple series arm resonators and multiple parallel arm resonators are configured of acoustic wave resonators. The acoustic wave filter is a surface acoustic wave filter using a surface acoustic wave, for example. In the surface acoustic wave filter, the multiple series arm resonators and the multiple parallel arm resonators are surface acoustic wave (SAW) resonators, for example.

The filter circuit 4A outputs a transmission signal to an antenna through an antenna terminal. For example, the filter circuit 4A outputs a transmission signal to the antenna 50a through the antenna terminal 2a described in Embodiment 1.

Hereinafter, the configurations of the first amplification unit 11A and the second amplification unit 12A will be described.

(1.1) First Amplification Unit

The first amplification unit 11A includes a first differential power amplifier 13A as illustrated in FIG. 4. The first differential power amplifier 13A amplifies the first transmission signal and outputs the amplified first transmission signal regardless of the power level of the inputted first transmission signal.

The first differential power amplifier 13A includes a first differential amplification element 101A, a second differential amplification element 102A, a first balun (unbalanced-balanced conversion circuit) 110A, and a first transformer 120A as illustrated in FIG. 4. The first balun 110A includes an input side primary coil L51 and an input side secondary coil L52 as illustrated in FIG. 4. The first transformer 120A includes an output side primary coil L53 and an output side secondary coil L54 as illustrated in FIG. 4.

The first differential power amplifier 13A further includes multiple (two in illustrated example) resistors R1 and R2, multiple (four in illustrated example) capacitors C1, C2, C51, and C52, a first inductor L55, and multiple (two in illustrated example) coils L56 as illustrated in FIG. 4.

One end of the resistor R1 is electrically connected to the terminal 10c. The other end of the resistor R1 is electrically connected to one end of the resistor R2. The other end of the resistor R2 is electrically connected to the ground. That is, the resistor R1 and resistor R2 are connected in series between the terminal 10c and the ground. A point between the resistor R1 and the resistor R2 is electrically connected to a point (midpoint, for example) between both ends of the input side secondary coil L52. That is, the other end of the resistor R1 and the one end of the resistor R2 are electrically connected to a point (midpoint, for example) between both the ends of the input side secondary coil L52.

One end (first end portion) of the first inductor L55 is electrically connected to the first differential amplification element 101A. The other end (second end portion) of the first inductor L55 is electrically connected to the second differential amplification element 102A.

One end (first end portion) of the coil L56 is electrically connected to the first differential amplification element 101A. The other end (second end portion) of the coil L56 is electrically connected to the second differential amplification element 102A. The first inductor L55 and the coil L56 are connected in parallel. The second bias voltage is supplied to the midpoint of the coil L56.

One end of the capacitor C51 is electrically connected to the first differential amplification element 101A and the first end portion of the coil L56. The other end of the capacitor C51 is electrically connected to the first end portion of the first inductor L55. One end of the capacitor C52 is electrically connected to the second differential amplification element 102A and the second end portion of the coil L56. The other end of the capacitor C52 is electrically connected to the second end portion of the first inductor L55. The capacitors C51 and C52 are DC cut capacitors to cut a DC component inputted to the first inductor L55.

One end of the coil L5 is electrically connected to the terminal 10d. The other end of the coil L5 is connected to one end of the capacitor C2. The other end of the capacitor C2 is electrically connected to the ground. That is, the coil L5 and the capacitor C2 are connected in series between the terminal 10d and the ground. A point between the coil L5 and the capacitor C2 is electrically connected to a point (midpoint, for example) between both ends of the coil L56. That is, the other end of the coil L5 and the one end of the capacitor C2 are electrically connected to a point (midpoint, for example) between both the ends of the coil L56.

One end of the capacitor C1 is electrically connected between the coil L5 and the terminal 10d, and the other end of the capacitor C1 is electrically connected to the ground.

One end of the input side primary coil L51 is electrically connected to the first input terminal 10a, and the other end of the input side primary coil L51 is electrically connected to the ground. One end (first balanced terminal) of the input side secondary coil L52 is electrically connected to the first differential amplification element 101A, and the other end (second balanced terminal) of the input side secondary coil L52 is electrically connected to the second differential amplification element 102A.

In a state that a first bias voltage is applied to the input side primary coil L51, a radio frequency signal (first transmission signal) outputted from the RF signal processing circuit 82 (see FIG. 1) is inputted to the first input terminal 10a. The first transmission signal is subjected to unbalanced-balanced conversion. At this time, a non-inverting input signal is outputted from the first balanced terminal of the input side secondary coil L52, and an inverting input signal is outputted from the second balanced terminal of the input side secondary coil L52.

The first differential amplification element 101A amplifies the non-inverting input signal outputted from the first balanced terminal of the input side secondary coil L52. The first differential amplification element 101A has an input terminal and an output terminal. The input terminal of the first differential amplification element 101A is electrically connected to the first balanced terminal of the input side secondary coil L52. The output terminal of the first differential amplification element 101A is electrically connected to the output side primary coil L53 of the first transformer 120A, the first inductor L55, and the coil L56. Specifically, the output terminal of the first differential amplification element 101A is electrically connected to one end (first end) of the output side primary coil L53, a first end of the first inductor L55, and a first end of the coil L56.

The second differential amplification element 102A amplifies an inverting input signal outputted from the second balanced terminal of the input side secondary coil L52. The second differential amplification element 102A has an input terminal and an output terminal. The input terminal of the second differential amplification element 102A is electrically connected to the second balanced terminal of the input side secondary coil L52. The output terminal of the second differential amplification element 102A is electrically connected to the output side primary coil L53 of the first transformer 120A, the first inductor L55, and the coil L56. Specifically, the output terminal of the second differential amplification element 102A is electrically connected to the other end (second end) of the output side primary coil L53, a second end of the first inductor L55, and a second end of the coil L56.

The first end of the output side primary coil L53 of the first transformer 120A is electrically connected to the first differential amplification element 101A, and the second end of the output side primary coil L53 is electrically connected to the second differential amplification element 102A. The output side primary coil L53 is connected in parallel with the first inductor L55 and the coil L56.

One terminal of the output side secondary coil L54 is electrically connected to the first output terminal 10b (simply referred to as “output terminal 10b” in Embodiment 2), and the other terminal of the output side secondary coil L54 is connected to the ground. The other terminal of the output side secondary coil L54 is connected to the ground through an output side quaternary coil L64 which will be described later. In other words, the first transformer 120A is electrically connected between the output terminals of the first differential amplification element 101A and the second differential amplification element 102A, and the output terminal 10b.

A non-inverting input signal amplified by the first differential amplification element 101A and an inverting input signal amplified by the second differential amplification element 102A are inputted to the coil L56 while maintaining the opposite phases, and are converted in impedance by the first inductor L55.

(1.2) Second Amplification Unit

The second amplification unit 12A includes a second differential power amplifier 15A as illustrated in FIG. 4. The second differential power amplifier 15A amplifies the second transmission signal and outputs the amplified second transmission signal, when the power level of the inputted second transmission signal becomes equal to or higher than the reference power level. The first differential power amplifier 13A and the second differential power amplifier 15A are used for simultaneous communication.

The second differential power amplifier 15A amplifies the second transmission signal. The second differential power amplifier 15A includes a third differential amplification element 201A, a fourth differential amplification element 202A, a second balun 210A, and a second transformer 220A as illustrated in FIG. 4. The second balun 210A includes an input side tertiary coil L61 and an input side quaternary coil L62 as illustrated in FIG. 4. The second transformer 220A includes an output side tertiary coil L63 and the output side quaternary coil L64 as illustrated in FIG. 4.

The second differential power amplifier 15A further includes multiple (two in illustrated example) resistors R21 and R22, multiple (four in illustrated example) capacitors C21, C22, C61, and C62, a second inductor L65, and multiple (two in illustrated example) coils L25 and L66 as illustrated in FIG. 4.

One end of the resistor R21 is electrically connected to the terminal 10g. The other end of the resistor R21 is electrically connected to one end of the resistor R22. The other end of the resistor R22 is electrically connected to the ground. That is, the resistor R21 and the resistor R22 are connected in series between the terminal 10g and the ground. A point between the resistor R21 and the resistor R22 is electrically connected to a point (midpoint, for example) between both ends of the input side quaternary coil L62. That is, the other end of the resistor R21 and the one end of the resistor R22 are electrically connected to a point (midpoint, for example) between both the ends of the input side quaternary coil L62.

One end (first end portion) of the second inductor L65 is electrically connected to the third differential amplification element 201A. The other end (second end portion) of the second inductor L65 is electrically connected to the fourth differential amplification element 202A.

One end (first end portion) of the coil L66 is electrically connected to the third differential amplification element 201A. The other end (second end portion) of the coil L66 is electrically connected to the fourth differential amplification element 202A. The second inductor L65 and the coil L66 are connected in parallel. The fourth bias voltage is supplied to the midpoint of the coil L66.

One end of the capacitor C61 is electrically connected to the third differential amplification element 201A and the first end portion of the coil L66. The other end of the capacitor C61 is electrically connected to the first end portion of the second inductor L65. One end of the capacitor C62 is electrically connected to the fourth differential amplification element 202A and the second end portion of the coil L66. The other end of the capacitor C62 is electrically connected to the second end portion of the second inductor L65. The capacitors C61 and C62 are DC cut capacitors to cut a DC component inputted to the second inductor L65.

One end of the coil L25 is electrically connected to the terminal 10h. The other end of the coil L25 is connected to one end of the capacitor C22. The other end of the capacitor C22 is electrically connected to the ground. That is, the coil L25 and the capacitor C22 are connected in series between the terminal 10h and the ground. A point between the coil L25 and the capacitor C22 is electrically connected to a point (midpoint, for example) between both ends of the coil L66. That is, the other end of the coil L25 and the one end of the capacitor C22 are electrically connected to a point (midpoint, for example) between both the ends of the coil L66.

One end of the capacitor C21 is electrically connected between the coil L25 and the terminal 10h, and the other end of the capacitor C21 is electrically connected to the ground.

One end of the input side tertiary coil L61 is electrically connected to the second input terminal 10e, and the other end of the input side tertiary coil L61 is electrically connected to the ground. One end (first balanced terminal) of the input side quaternary coil L62 is electrically connected to the third differential amplification element 201A, and the other end (second balanced terminal) of the input side quaternary coil L62 is electrically connected to the fourth differential amplification element 202A.

In a state that a third bias voltage is applied to the input side tertiary coil L61, a radio frequency signal (second transmission signal) outputted from the RF signal processing circuit 82 (see FIG. 1) is inputted to the second input terminal 10e. The second transmission signal is subjected to unbalanced-balanced conversion. At this time, a non-inverting input signal is outputted from the first balanced terminal of the input side quaternary coil L62, and an inverting input signal is outputted from the second balanced terminal of the input side quaternary coil L62.

The third differential amplification element 201A amplifies a non-inverting input signal outputted from the first balanced terminal of the input side quaternary coil L62. The third differential amplification element 201A has an input terminal and an output terminal. The input terminal of the third differential amplification element 201A is electrically connected to the first balanced terminal of the input side quaternary coil L62. The output terminal of the third differential amplification element 201A is electrically connected to the output side tertiary coil L63 of the second transformer 220A, the second inductor L65, and the coil L66. Specifically, the output terminal of the third differential amplification element 201A is electrically connected to one end (first end) of the output side tertiary coil L63, a first end of the second inductor L65, and a first end of the coil L66.

The fourth differential amplification element 202A amplifies an inverting input signal outputted from the second balanced terminal of the input side quaternary coil L62. The fourth differential amplification element 202A has an input terminal and an output terminal. The input terminal of the fourth differential amplification element 202A is electrically connected to the second balanced terminal of the input side quaternary coil L62. The output terminal of the fourth differential amplification element 202A is electrically connected to the output side tertiary coil L63 of the second transformer 220A, the second inductor L65, and the coil L66. Specifically, the output terminal of the fourth differential amplification element 202A is electrically connected to the other end (second end) of the output side tertiary coil L63, a second end of the second inductor L65, and a second end of the coil L66.

The first end of the output side tertiary coil L63 of the second transformer 220A is electrically connected to the third differential amplification element 201A, and the second end of the output side tertiary coil L63 is electrically connected to the fourth differential amplification element 202A. The output side tertiary coil L63 is connected in parallel with the second inductor L65 and the coil L66.

One terminal of the output side quaternary coil L64 is electrically connected to the output terminal 10b (simply referred to as “output terminal 10b” in Embodiment 2), and the other terminal of the output side quaternary coil L64 is connected to the ground. The one terminal of the output side quaternary coil L64 is electrically connected to the output terminal 10b through the output side secondary coil L54. In other words, the second transformer 220A is electrically connected between the output terminals of the third differential amplification element 201A and the fourth differential amplification element 202A, and the output terminal 10b.

A non-inverting input signal amplified by the third differential amplification element 201A and an inverting input signal amplified by the fourth differential amplification element 202A are inputted to the coil L66 while maintaining the opposite phases, and are converted in impedance by the second inductor L65.

(2) Arrangement Configuration

Here, the arrangement configuration of the first amplification unit 11A and the second amplification unit 12A will be described with reference to FIG. 5. Note that, in FIG. 5, a direction in which the first input terminal 10a and the output terminal 10b are arranged is defined as a right and left direction. In FIG. 5, a direction in which the first input terminal 10a and the second input terminal 10e are arranged is defined as a front and back direction. Further, in FIG. 5, a direction (front and back direction of paper surface) orthogonal to both the right and left direction and the front and back direction is defined as an up and down direction. A direction from the first input terminal 10a toward the output terminal 10b is defined as a rightward direction, and a direction from the output terminal 10b toward the first input terminal 10a is defined as a leftward direction. A direction from the first input terminal 10a toward the second input terminal 10e is defined as a forward direction, and a direction from the second input terminal 10e toward the first input terminal 10a is defined as a backward direction. A direction from the inside of a substrate 300A toward a mounting surface 301A is defined as an upward direction, and a direction from the mounting surface 301A toward the inside of the substrate 300A is defined as a downward direction.

The first amplification unit 11A and the second amplification unit 12A are provided in or on the substrate 300A.

First, the arrangement in the first amplification unit 11A will be described.

The first differential amplification element 101A, the second differential amplification element 102A, and the first balun 110A are integrated into one chip. That is, a first chip 310A includes the first differential amplification element 101A, the second differential amplification element 102A, and the first balun 110A (see FIG. 5). The first differential amplification element 101A, the second differential amplification element 102A, and the first balun 110A are arranged inside the first chip 310A. The first chip 310A is arranged on the mounting surface 301A of the substrate 300A. Note that the first chip 310A may partially be buried in the substrate 300A. Although the first differential amplification element 101A, the second differential amplification element 102A, and the first balun 110A are arranged inside the first chip 310A, they are illustrated with the solid lines in FIG. 5.

The input side primary coil L51 of the first balun 110A is wound counterclockwise starting from one end, which is closer to the first input terminal 10a, of both ends of the input side primary coil L51. The input side secondary coil L52 of the first balun 110A is provided inside the first chip 310A at a position closer than the input side primary coil L51 to the substrate 300A. The input side primary coil L51 is arranged to overlap the input side secondary coil L52 in plan view of the substrate 300A.

The output side primary coil L53 of the first transformer 120A is formed inside the substrate 300A. The output side secondary coil L54 of the first transformer 120A is wound clockwise starting from one end, which is closer to the output terminal 10b, of both the ends of the output side secondary coil L4. The output side secondary coil L54 is arranged to overlap the output side primary coil L53 in plan view of the substrate 300A. Although the output side primary coil L53 is arranged inside the substrate 300A, it is illustrated with the solid line in FIG. 5.

The first inductor L55 is formed of an inductor chip having a substantially rectangular parallelepiped shape. The first inductor L55 is arranged on the mounting surface 301A of the substrate 300A. Note that the first inductor L55 may partially be buried in the substrate 300A.

A conductive wire is wound while making a winding axis, extending along a direction orthogonal to a long-side direction, as a center to form the first inductor L55.

The first inductor L55 and the coil L56 are arranged such that the directions of the generated magnetic flux are different from each other. For example, the first inductor L55 is arranged such that the generated magnetic flux P53 is directed leftward in plan view of the substrate 300A. The coil L56 is arranged such that the generated magnetic flux is directed downward or upward in plan view of the substrate 300A.

Next, the arrangement in the second amplification unit 12A will be described.

The third differential amplification element 201A, the fourth differential amplification element 202A, and the second balun 210A are integrated into one chip. That is, a second chip 320A includes the third differential amplification element 201A, the fourth differential amplification element 202A, and the second balun 210A (see FIG. 5). The third differential amplification element 201A, the fourth differential amplification element 202A, and the second balun 210A are arranged inside the second chip 320A. The second chip 320A is arranged on the mounting surface 301A of the substrate 300A. Note that the second chip 320A may partially be buried in the substrate 300A. Although the third differential amplification element 201A, the fourth differential amplification element 202A, and the second balun 210A are arranged inside the second chip 320A, they are illustrated with the solid lines in FIG. 5.

The input side tertiary coil L61 of the second balun 210A is wound clockwise starting from one end, which is closer to the second input terminal 10e, of both ends of the input side tertiary coil L61. The input side quaternary coil L62 of the second balun 210A is provided inside the second chip 320A at a position closer than the input side tertiary coil L61 to the substrate 300A. The input side tertiary coil L61 is arranged to overlap the input side quaternary coil L62 in plan view of the substrate 300A.

The output side tertiary coil L63 of the second transformer 220A is formed inside the substrate 300A. The output side quaternary coil L64 of the second transformer 220A is wound clockwise starting from one end, which is closer to the output terminal 10b, of both ends of the output side quaternary coil L64. The output side quaternary coil L64 is arranged to overlap the output side tertiary coil L63 in plan view of the substrate 300A. Although the output side tertiary coil L63 is arranged inside the substrate 300A, it is illustrated with the solid line in FIG. 5.

The second inductor L65 is formed of an inductor chip having a substantially rectangular parallelepiped shape. The second inductor L65 is arranged on the mounting surface 301A of the substrate 300A. Note that the second inductor L65 may partially be buried in the substrate 300A.

The second inductor L65 and the coil L66 are arranged such that the directions of the generated magnetic flux are different from each other. For example, the second inductor L65 is arranged such that the generated magnetic flux P63 is directed rightward in plan view of the substrate 300A. The coil L66 is arranged such that the generated magnetic flux is directed downward or upward in plan view of the substrate 300A.

The first inductor L55 and the second inductor L65 are present at relatively the same position in a circuit forming the first amplification unit 11A and a circuit forming the second amplification unit 12A. Further, the direction of the magnetic flux P53 generated in the first inductor L55 is the leftward direction, and the direction of the magnetic flux P63 generated in the second inductor L65 is the rightward direction.

A conductor forming the input side primary coil L51 of the first balun 110A is wound counterclockwise, and a conductor forming the input side tertiary coil L61 of the second balun 210A is wound clockwise. As a result, the direction of magnetic flux P51 generated by a current flowing through the input side primary coil L51 is the upward direction, and the direction of magnetic flux P61 generated by a current flowing through the input side tertiary coil L61 is the downward direction. That is, when the first transmission signal is inputted to the first input terminal 10a, that is, when a current is inputted to the first input terminal 10a, the magnetic flux P51 is generated in the upward direction in the first balun 110A. When the second transmission signal is inputted to the second input terminal 10e, that is, when a current is inputted to the second input terminal 10e, the magnetic flux P61 is generated in the downward direction in the second balun 210A. That is, the first balun 110A and the second balun 210A are configured such that the directions of the generated magnetic flux are different from each other.

When a current flows through the output side secondary coil L54 of the first transformer 120A, the direction of magnetic flux P52 generated in the output side secondary coil L54 is upward direction. Further, the direction of magnetic flux P62 generated by a current flowing through the output side quaternary coil L64 is the downward direction. That is, when the first transmission signal is inputted to the first transformer 120A, that is, when a current is inputted to the first transformer 120A, the magnetic flux P52 is generated in the upward direction in the first transformer 120A. When the second transmission signal is inputted to the second transformer 220A, that is, when a current is inputted to the second transformer 220A, the magnetic flux P62 is generated in the downward direction in the second transformer 220A. That is, the first transformer 120A and the second transformer 220A are configured such that the directions of the generated magnetic flux are different from each other.

That is, the radio frequency module 1A of Embodiment 2 is configured such that the first magnetic flux (magnetic flux P51, for example) generated on the input side of the first differential power amplifier 13A and the second magnetic flux (magnetic flux P61, for example) generated on the input side of the second differential power amplifier 15A have directions different from each other. Further, the third magnetic flux (magnetic flux P52, for example) generated on an output side of the first differential power amplifier 13A and the fourth magnetic flux (magnetic flux P62, for example) generated on an output side of the second differential power amplifier 15A are configured to have directions different from each other.

Note that, it is not necessary that both the following conditions are met. The first condition is that the first balun 110A and the second balun 210A are configured such that the directions of the generated magnetic flux are different from each other. The second condition is that the first transformer 120A and the second transformer 220A are configured such that the directions of the generated magnetic flux are different from each other. It is sufficient that the first differential power amplifier 13A and the second differential power amplifier 15A are provided to realize at least one of the configurations described as follows. The first configuration is a configuration in which the first magnetic flux (magnetic flux P51) generated on the input side of the first differential power amplifier 13A and the second magnetic flux (magnetic flux P61) generated on the input side of the second differential power amplifier 15A have directions different from each other. The second configuration is a configuration in which the third magnetic flux (magnetic flux P52) generated on the output side of the first differential power amplifier 13A and the fourth magnetic flux (magnetic flux P62) generated on the output side of the second differential power amplifier 15A have directions different from each other. That is, the first configuration is realized when the first balun 110A and the second balun 210A are configured such that the directions of the generated magnetic flux are different from each other. The second configuration is realized when the first transformer 120A and the second transformer 220A are configured such that the directions of the generated magnetic flux are different from each other.

Although the winding direction of the input side primary coil L51 of the first balun 110A and the winding direction of the input side tertiary coil L61 of the second balun 210A are described as different from each other, the present disclosure is not limited to this configuration. The winding direction of the input side secondary coil L52 of the first balun 110A and the winding direction of the input side quaternary coil L62 of the second balun 210 may be different from each other. Alternatively, the winding direction of the input side primary coil L51 of the first balun 110A and the winding direction of the input side quaternary coil L62 of the second balun 210A may be different from each other. Alternatively, the winding direction of the input side secondary coil L52 of the first balun 110A and the winding direction of the input side tertiary coil L61 of the second balun 210A may be different from each other. That is, it is sufficient that the winding direction of one coil of the input side primary coil L51 and the input side secondary coil L52 of the first balun 110A, and the winding direction of one coil of the input side tertiary coil L61 and the input side quaternary coil L62 of the second balun 210A, are configured different from each other.

Although the winding direction of the output side secondary coil L54 of the first transformer 120A and the winding direction of the output side quaternary coil L64 of the second transformer 220A are described as different from each other, the present disclosure is not limited to this configuration. The winding direction of the output side primary coil L53 of the first transformer 120A and the winding direction of the output side tertiary coil L63 of the second transformer 220A may be different from each other. Alternatively, the winding direction of the output side primary coil L53 of the first transformer 120A and the winding direction of the output side quaternary coil L64 of the second transformer 220A may be different from each other. Alternatively, the winding direction of the output side secondary coil L54 of the first transformer 120A and the winding direction of the output side tertiary coil L63 of the second transformer 220A may be different from each other. That is, it is sufficient that the winding direction of one coil of the output side primary coil L53 and the output side secondary coil L54 of the first transformer 120A, and the winding direction of one coil of the output side tertiary coil L63 and the output side quaternary coil L64 of the second transformer 220A, are configured different from each other.

(3) Operation

An operation of the radio frequency module 1A includes a first operation and a second operation. In the first operation, both the first amplification unit 11A and the second amplification unit 12A operate. That is, during the first operation, all of the first differential amplification element 101A, the second differential amplification element 102A, the third differential amplification element 201A, and the fourth differential amplification element 202A operate. In the second operation, the first amplification unit 11A operates and the second amplification unit 12A does not operate. That is, in the second operation, the first differential amplification element 101A and the second differential amplification element 102A operate, and the third differential amplification element 201A and the fourth differential amplification element 202A do not operate.

In the first operation, the power level of the second transmission signal inputted to the second amplification unit 12A is equal to or higher than a reference power level. The “reference power level” is defined as power that is substantially twice the power inputted to the second amplification unit 12A, when the output power of the first amplification unit 11A and the output power of the second amplification unit 12A are equal to each other, for example. Further, the “reference power level” is defined by the power from the saturation of the first amplification unit 11A to the start of output of the second amplification unit 12A, when input power to the first amplification unit 11A and the second amplification unit 12A is gradually increased, for example. That is, when the power level of the second transmission signal inputted to the second amplification unit 12A reaches equal to or higher than the reference power level, the second amplification unit 12A amplifies the second transmission signal and outputs the amplified second transmission signal. Meanwhile, the first amplification unit 11A amplifies the first transmission signal and outputs the amplified first transmission signal regardless of the power level of the first transmission signal inputted to the first amplification unit 11A.

In the second operation, the input power to the third differential amplification element 201A and the fourth differential amplification element 202A decreases, and the output power of the third differential amplification element 201A and the fourth differential amplification element 202A approaches zero. Accordingly, the second amplification unit 12A falls in a state being disconnected from the second transformer 220A. With this, in the radio frequency module 1A, during the second operation, the first amplification unit 11A amplifies the first transmission signal inputted to the first amplification unit 11A and outputs the amplified first transmission signal. Meanwhile, in the radio frequency module 1A, the second amplification unit 12A does not operate during the second operation.

(4) Modification

Modifications will be listed below.

In Embodiment 2, a pair of the first balun 110A and the second balun 210A, a pair of the first transformer 120A and the second transformer 220A, and a pair of the first inductor L55 and the second inductor L65 have an arrangement configuration in which directions of the generated magnetic flux are different from each other, but the present disclosure is not limited to this configuration. It is acceptable that at least one of the pair of the first balun 110A and the second balun 210A, the pair of the first transformer 120A and the second transformer 220A, and the pair of the first inductor L55 and the second inductor L65 is arranged such that the directions of the generated magnetic flux are different from each other.

Further, the coil L56 and the coil L66 may be arranged such that the directions of the generated magnetic flux are different from each other.

Modification 3 and Modification 5 described in Embodiment 1 may be applied to Embodiment 2.

### CONCLUSION

As described above, a radio frequency module (1; 1A) of a first aspect includes a first transformer (120; 120A) and a second transformer (220; 220A). The first transformer (120; 120A) is included in a first differential power amplifier (13; 13A) to amplify a first transmission signal. The second transformer (220; 220A) is included in a second differential power amplifier (15; 15A) to amplify a second transmission signal to be simultaneously communicated with the first transmission signal. A direction of magnetic flux (P2; P52) generated in the first transformer (120; 120A) and a direction of magnetic flux (P4; P62) generated in the second transformer (220; 220A) are different from each other.

With the configuration above, it is possible to suppress a decrease in isolation when both a first transmission signal and a second transmission signal are transmitted in simultaneous communication.

A radio frequency module (1; 1A) of a second aspect includes a first balun (110; 110A) and a second balun (210; 210A). The first balun (110; 110A) is included in a first differential power amplifier (13; 13A) to amplify a first transmission signal. The second balun (210; 210A) is included in a second differential power amplifier (15; 15A) to amplify a second transmission signal to be simultaneously communicated with the first transmission signal. A direction of magnetic flux (P1; P51) generated in the first balun (110; 110A) and a direction of magnetic flux (P3; P61) generated in the second balun (210; 210A) are different from each other.

With the configuration above, it is possible to suppress a decrease in isolation when both a first transmission signal and a second transmission signal are transmitted in simultaneous communication.

In a radio frequency module (1; 1A) of a third aspect, in the second aspect, the first differential power amplifier (13; 13A) further includes a first transformer (120; 120A). The second differential power amplifier (15; 15A) further includes a second transformer (220; 220A). A direction of magnetic flux (P2; P52) generated in the first transformer (120; 120A) and a direction of magnetic flux (P4; P62) generated in the second transformer (220; 220A) are different from each other.

With the configuration above, it is possible to suppress a decrease in isolation when both a first transmission signal and a second transmission signal are transmitted in simultaneous communication.

A radio frequency module (1) of a fourth aspect includes a first power amplifier (first differential power amplifier 13, for example), a second power amplifier (second differential power amplifier 15, for example), a first inductor (inductor L11, for example), and a second inductor (inductor L31, for example). The first power amplifier amplifies a first transmission signal. The second power amplifier amplifies a second transmission signal simultaneously communicated with the first transmission signal. The first inductor is connected to an output side of the first power amplifier. The second inductor is connected to an output side of the second power amplifier. A direction of magnetic flux (magnetic flux P11, for example) generated in the first inductor and a direction of magnetic flux (magnetic flux P21, for example) generated in the second inductor are different from each other.

With the configuration above, it is possible to suppress a decrease in isolation when both a first transmission signal and a second transmission signal are transmitted in simultaneous communication.

In a radio frequency module (1) of a fifth aspect, in the fourth aspect, the multiple first inductors are connected to the output side of the first power amplifier. The multiple second inductors are connected to the output side of the second power amplifier. With respect to the multiple first inductors and the multiple second inductors, for each pair of a first inductor and a second inductor based on a distance, directions of magnetic flux generated in the first inductor and the second inductor of the pair are different from each other.

With the configuration above, it is possible to suppress a decrease in isolation when both a first transmission signal and a second transmission signal are transmitted in simultaneous communication.

In a radio frequency module (1) of a sixth aspect, in the fourth aspect, the multiple first inductors are connected to the output side of the first power amplifier. The multiple second inductors are connected to the output side of the second power amplifier. With respect to the multiple first inductors and the multiple second inductors, for each pair of a first inductor and a second inductor arranged at relatively the same position as circuits, directions of magnetic flux generated in the first inductor and the second inductor of the pair are different from each other.

With the configuration above, it is possible to suppress a decrease in isolation when both a first transmission signal and a second transmission signal are transmitted in simultaneous communication.

In a radio frequency module (1) of a seventh aspect, in the fifth or sixth aspect, the multiple first inductors are arranged such that directions of magnetic flux are different from each other.

With the configuration above, a decrease in quality of a first transmission signal may be suppressed.

In a radio frequency module (1) of an eighth aspect, in any of the fifth to seventh aspects, the multiple second inductors are arranged such that directions of magnetic flux are different from each other.

With the configuration above, a decrease in quality of a first transmission signal may be suppressed.

In a radio frequency module (1) of a ninth aspect, in any of the fourth to eighth aspects, the first power amplifier is a first differential power amplifier (13). The second power amplifier is a second differential power amplifier (15). The first differential power amplifier (13) includes a first transformer (120). The second differential power amplifier (15) includes a second transformer (220). A direction of magnetic flux (P2) generated in the first transformer (120) and a direction of magnetic flux (P4) generated in the second transformer (220) are different from each other.

With the configuration above, it is possible to further suppress a decrease in isolation when both a first transmission signal and a second transmission signal are transmitted in simultaneous communication.

In a radio frequency module (1) of a tenth aspect, in any of the fourth to ninth aspects, the first power amplifier is a first differential power amplifier (13). The second power amplifier is a second differential power amplifier (15). The first differential power amplifier (13) includes a first balun (110). The second differential power amplifier (15) includes a second balun (210). A direction of magnetic flux (P1) generated in the first balun (110) is different from a direction of magnetic flux (P3) generated in the second balun (210).

With the configuration above, it is possible to further suppress a decrease in isolation when both a first transmission signal and a second transmission signal are transmitted in simultaneous communication.

In a radio frequency module (1) of an eleventh aspect, in any of the first to tenth aspects, the first transmission signal is a signal of a first frequency band defined by the fourth generation mobile communication standard. The second transmission signal is a signal of a second frequency band defined by the fourth generation mobile communication standard.

With the configuration above, it is possible to suppress a decrease in isolation when a signal in the first frequency band defined by the fourth generation mobile communication standard and a signal in the second frequency band defined by the fourth generation mobile communication standard are transmitted in simultaneous communication.

In a radio frequency module (1) of a twelfth aspect, in any of the first to tenth aspects, the first transmission signal is a signal of a first frequency band defined by the fifth generation mobile communication standard. The second transmission signal is a signal of a second frequency band defined by the fifth generation mobile communication standard.

With the configuration above, it is possible to suppress a decrease in isolation when a signal in the first frequency band defined by the fifth generation mobile communication standard and a signal in the second frequency band defined by the fifth generation mobile communication standard are transmitted in simultaneous communication.

In a radio frequency module (1) of a thirteenth aspect, in any of the first to tenth aspects, one transmission signal of the first transmission signal and the second transmission signal is a signal in the first frequency band defined by the fourth generation mobile communication standard. The other transmission signal of the first transmission signal and the second transmission signal is a signal of the second frequency band defined by the fifth generation mobile communication standard.

With the configuration above, it is possible to suppress a decrease in isolation when a signal in the first frequency band defined by the fourth generation mobile communication standard and a signal in the second frequency band defined by the fifth generation mobile communication standard are transmitted in simultaneous communication.

In a radio frequency module (1A) of a fourteenth aspect, in any of the first to third aspects, the first differential power amplifier (13A) amplifies the first transmission signal and outputs the amplified first transmission signal regardless of a power level of the inputted first transmission signal. The second differential power amplifier (15A) amplifies the second transmission signal and outputs the amplified second transmission signal when a power level of the inputted second transmission signal reaches equal to or higher than a reference power level.

With the configuration above, a decrease in isolation may be suppressed when transmission is performed in simultaneous communication.

In a radio frequency module (1A) of a fifteenth aspect, in the fourteenth aspect, the first differential power amplifier (13A) includes a first inductor (L55). The second differential power amplifier (15A) includes a second inductor (L65). A direction of magnetic flux (P63) generated in the first inductor (L55) and a direction of magnetic flux (P63) generated in the second inductor (L65) are different from each other.

With the configuration above, a decrease in isolation may be suppressed when transmission is performed in simultaneous communication.

A communication device (500) of a sixteenth aspect includes the radio frequency module (1) of any of the first to fifteenth aspects, and a signal processing circuit (80) to process a radio frequency signal passing through the radio frequency module (1).

With the configuration above, it is possible to suppress a decrease in isolation when both a first transmission signal and a second transmission signal are transmitted in simultaneous communication.

1, 1A RADIO FREQUENCY MODULE

2a, 2b ANTENNA TERMINAL

3 ANTENNA SWITCH

4 FIRST TRANSMISSION FILTER

4A FILTER CIRCUIT

5 SECOND TRANSMISSION FILTER

10, 10A AMPLIFICATION UNIT

10a FIRST INPUT TERMINAL

10b FIRST OUTPUT TERMINAL (OUTPUT TERMINAL)

10c, 10d TERMINAL

10e SECOND INPUT TERMINAL

10f SECOND OUTPUT TERMINAL

10g, 10h TERMINAL

11, 11A FIRST AMPLIFICATION UNIT

12, 12A SECOND AMPLIFICATION UNIT

13, 13A FIRST DIFFERENTIAL POWER AMPLIFIER

14 FIRST OUTPUT MATCHING CIRCUIT

15, 15A SECOND DIFFERENTIAL POWER AMPLIFIER

16 SECOND OUTPUT MATCHING CIRCUIT

31a, 31b COMMON TERMINAL

32, 33 SELECTION TERMINAL

50a, 50b ANTENNA

80 SIGNAL PROCESSING CIRCUIT

81 BASEBAND SIGNAL PROCESSING CIRCUIT

82 RF SIGNAL PROCESSING CIRCUIT

101, 101A FIRST DIFFERENTIAL AMPLIFICATION ELEMENT

102, 102A SECOND DIFFERENTIAL AMPLIFICATION ELEMENT

110, 110A FIRST BALUN (UNBALANCED-BALANCED CONVERSION CIRCUIT)

120, 120A FIRST TRANSFORMER

201, 201A THIRD DIFFERENTIAL AMPLIFICATION ELEMENT

202, 202A FOURTH DIFFERENTIAL AMPLIFICATION ELEMENT

210, 210A SECOND BALUN

220, 220A SECOND TRANSFORMER

300, 300A SUBSTRATE

301, 301A MOUNTING SURFACE

310, 310A FIRST CHIP

320, 320A SECOND CHIP

500 COMMUNICATION DEVICE

C1, C2, C11, C12, C13, C21, C22, C31, C32, C33, C51, C52, C61, C62 CAPACITOR

L1, L51 INPUT SIDE PRIMARY COIL

L2, L52 INPUT SIDE SECONDARY COIL

L3, L53 OUTPUT SIDE PRIMARY COIL

L4, L54 OUTPUT SIDE SECONDARY COIL

L5, L25, L56, L66 COIL

L55 FIRST INDUCTOR

L11, L12, L13, L31, L32, L33 INDUCTOR

L21, L61 INPUT SIDE TERTIARY COIL

L22, L62 INPUT SIDE QUATERNARY COIL

L23, L63 OUTPUT SIDE TERTIARY COIL

L24, L64 OUTPUT SIDE QUATERNARY COIL

L65 SECOND INDUCTOR

P1, P2, P3, P4, P11, P12, P13, P21, P22, P23, P51, P52, P53, P61, P62, P63 MAGNETIC FLUX

R1, R2, R21, R22 RESISTOR

1. A radio frequency module, comprising:
a first differential power amplifier configured to amplify a first transmission signal and comprising a first transformer; and
a second differential power amplifier configured to amplify a second transmission signal to be simultaneously communicated with the first transmission signal and comprising a second transformer,
wherein a first direction of magnetic flux generated in the first transformer and a second direction of magnetic flux generated in the second transformer are different from each other.

2. A radio frequency module, comprising:
a first differential power amplifier configured to amplify a first transmission signal and comprising a first balun; and
a second differential power amplifier configured to amplify a second transmission signal to be simultaneously communicated with the first transmission signal and comprising a second balun,
wherein a first direction of magnetic flux generated in the first balun and a second direction of magnetic flux generated in the second balun are different from each other.

3. The radio frequency module according to claim 2,
wherein the first differential power amplifier further comprises a first transformer,
the second differential power amplifier further comprises a second transformer, and
a third direction of magnetic flux generated in the first transformer and a fourth direction of magnetic flux generated in the second transformer are different from each other.

4. A radio frequency module, comprising:
a first power amplifier configured to amplify a first transmission signal;
a second power amplifier configured to amplify a second transmission signal to be simultaneously communicated with the first transmission signal;
a first inductor connected to an output side of the first power amplifier; and
a second inductor connected to an output side of the second power amplifier,
wherein a first direction of magnetic flux generated in the first inductor and a second direction of magnetic flux generated in the second inductor are different from each other.

5. The radio frequency module according to claim 4,
wherein a plurality of first inductors are connected to the output side of the first power amplifier,
a plurality of second inductors are connected to the output side of the second power amplifier, and
with respect to a plurality of pairs of inductors each comprising one of the plurality of first inductors and one of the plurality of second inductors selected based on distance, for each of the pairs, directions of magnetic flux generated in the first inductor and the second inductor of the pair are different from each other.

6. The radio frequency module according to claim 4,
wherein a plurality of first inductors are connected to the output side of the first power amplifier,
a plurality of second inductors are connected to the output side of the second power amplifier, and
with respect to a plurality of pairs of inductors each comprising one of the plurality of first inductors and one of the plurality of second inductors arranged at relatively a same position as circuits, for each of the pairs, directions of magnetic flux generated in the first inductor and the second inductor of the pair are different from each other.

7. The radio frequency module according to claim 5,
wherein in the plurality of first inductors, directions of magnetic flux are different from each other.

8. The radio frequency module according to claim 5,
wherein in the plurality of second inductors, directions of magnetic flux are different from each other.

9. The radio frequency module according to claim 4,
wherein the first power amplifier comprises a first differential power amplifier,
the second power amplifier comprises a second differential power amplifier,
the first differential power amplifier comprises a first transformer,
the second differential power amplifier comprises a second transformer, and
a third direction of magnetic flux generated in the first transformer and a fourth direction of magnetic flux generated in the second transformer are different from each other.

10. The radio frequency module according to claim 4,
wherein the first power amplifier comprises a first differential power amplifier,
the second power amplifier comprises a second differential power amplifier,
the first differential power amplifier comprises a first balun,
the second differential power amplifier comprises a second balun, and
a third direction of magnetic flux generated in the first balun and a fourth direction of magnetic flux generated in the second balun are different from each other.

11. The radio frequency module according to claim 1,
wherein the first transmission signal comprises a signal in a first frequency band that is defined by a fourth generation mobile communication standard, and
the second transmission signal comprises a signal in a second frequency band that is defined by the fourth generation mobile communication standard.

12. The radio frequency module according to claim 1,
wherein the first transmission signal comprises a signal in a first frequency band that is defined by a fifth generation mobile communication standard, and
the second transmission signal comprises a signal in a second frequency band that is defined by the fifth generation mobile communication standard.

13. The radio frequency module according to claim 1,
wherein one of the first transmission signal or the second transmission signal comprises a signal in a first frequency band that is defined by a fourth generation mobile communication standard, and the other of the first transmission signal or the second transmission signal comprises a signal in a second frequency band that is defined by a fifth generation mobile communication standard.

14. The radio frequency module according to claim 1,
wherein the first differential power amplifier is configured to output the amplified first transmission signal regardless of a power level of the first transmission signal inputted, and
the second differential power amplifier is configured to output the amplified second transmission signal when a power level of the second transmission signal inputted reaches equal to or higher than a reference power level.

15. The radio frequency module according to claim 14,
wherein the first differential power amplifier further comprises a first inductor,
the second differential power amplifier further comprises a second inductor, and
a third direction of magnetic flux generated in the first inductor and a fourth direction of magnetic flux generated in the second inductor are different from each other.

16. A communication device, comprising:
the radio frequency module according to claim 1; and
a signal processing circuit configured to process a radio frequency signal passing through the radio frequency module.

17. The radio frequency module according to claim 6,
wherein in the plurality of first inductors, directions of magnetic flux are different from each other.

18. The radio frequency module according to claim 6,
wherein in the plurality of second inductors, directions of magnetic flux are different from each other.

19. The radio frequency module according to claim 7,
wherein in the plurality of second inductors, directions of magnetic flux are different from each other.

20. The radio frequency module according to claim 2,
wherein one of the first transmission signal or the second transmission signal comprises a signal in a first frequency band that is defined by a fourth generation mobile communication standard, and the other of the first transmission signal or the second transmission signal comprises a signal in a second frequency band that is defined by a fifth generation mobile communication standard.
